(19) United States
(12) Patent Application Publication
(10) Pub. No.: US 2011/0193212 A1
(43) Pub. Date: Aug. 11, 2011

(54) Systems and Methods Providing Arrangements of Vias

(75) Inventors: Shiqun Gu, San Diego, CA (US); Matthew Michael Nowak, San Diego, CA (US); Durodami J. Lisk, San Diego, CA (US); Thomas R. Toms, Dripping Springs, TX (US); Urmi Ray, Ramona, CA (US); Jungwon Suh, San Diego, CA (US); Arvind Chandrasekaran, San Diego, CA (US)

(73) Assignee: QUALCOMM INCORPORATED, San Diego, CA (US)

(21) Appl. No.: 12/701,642

(22) Filed: Feb. 8, 2010

(51) Int. Cl. H01L 23/522; H01L 21/768

(52) U.S. Cl. 257/686; 438/109; 257/E25.013; 257/E23.145; 257/E21.575

(57) ABSTRACT

A semiconductor chip includes an array of electrical contacts and multiple vias coupling at least one circuit in the semiconductor chip to the array of electrical contacts. A first one of the electrical contacts of the array of electrical contacts is coupled to N vias, and a second one of the electrical contacts of the array of electrical contacts is coupled to M vias. M and N are positive integers of different values.

### TECHNICAL FIELD

The present description generally relates to arrangements of features in semiconductor circuits and, more specifically, to arrangements of vias.

### BACKGROUND

FIG. 1 is an illustration of an exemplary, conventional chip package 100. The chip package 100 includes a wide input/output (I/O) memory chip 101 mounted on top of a logic chip 102. The chips 101 and 102 are mounted onto a package substrate 104 using, e.g., an adhesive. The logic chip 102 is in electrical communication with contacts (not shown) on the substrate 102 using a wire bond 105.

The chips 101 and 102 are shown electrically coupled to each other using ball grid arrays 103, 106. Specifically, the memory chip 101 includes ball grid array 103 (shown from the side), and the logic chip 102 includes the ball grid array 106 (also shown from the side). The respective ball grid arrays 103 and 106 are aligned with each other, and contact is made therebetween so that the chips 101 and 102 communicate.

FIG. 2 is an illustration of a conventional, exemplary layout for the memory chip 101 (FIG. 1). The memory, itself, is divided into eight banks 201-208. The wide I/O interface (e.g., 103 of FIG. 1) is divided into four channels 211-214. Each of the respective banks 201-208 is served by a channel, and each of the channels 211-214 serves two of the banks.

Channels, such as the channels 211-214, can come in any of a variety of shapes and sizes. One example of a ball grid array includes four channels, where each channel is approximately 5 millimeters by 0.6 millimeters, including six rows by forty-eight columns of balls. While not shown herein, in some conventional systems, there is a Redistribution Layer (RDL) under each of the ball grid arrays 103, 106 that couples each of the solder balls to respective memory elements (in the case of the memory chip 101) or to logic circuits (in the case of the logic chip 102). In other conventional systems, Through Silicon Vias (TSVs) connect the solder balls to their respective logic circuits in the logic chip 102.

FIG. 3 is an illustration of an exemplary, conventional ball grid array 300 for use with either the memory chip 101 or the logic chip 102. Four channels 301-304 are shown truncated for ease of illustration. For simplicity, only three kinds of contacts are shown—power contacts, ground contacts, and signal contacts, which are indicated in FIG. 3 by shading. The ball grid array 300 includes an arrangement of contacts wherein power and ground connections are not only at the periphery of the ball grid array 300, but in the central area of the ball grid array 300 as well. For instance, power contacts 310-314 are located around the periphery of the ball grid array 300, whereas the power contacts 315-318 are located around the central area of the ball grid array 300.

The arrangement in FIG. 3 has a few disadvantages. For instance, more routing resources are used to make the TSVs between the respective power and ground contacts and power and ground layers vertical when a contact and its respective layer are not in the same column. Similarly, more horizontal routing resources are used when a contact and its respective layer are not in the same row. As the power and ground contacts desire a low resistance path to the upper layer metals nearly all of the routing resources are consumed in the TSVs. In other words, conventional designs use more routing resources where the TSVs are spread out using more rows and/or columns. Additionally, when the backside metal layer is to be used to short TSVs and contacts of the same node the contacts and TSVs are conventionally shorted by separate BGA Semiauto Mounter (BSM) islands. Use of separate BSM islands for a group of contacts each providing power (or ground) is somewhat complex and inefficient. Accordingly, the ball grid array 300 could be improved.

Returning to FIG. 1, it is noted that the memory chip 101 is placed upon the logic chip 102 so that balls of the ball grid arrays 103, 106 are in contact with each other. However, the ball grid array 103 does not cover the entire surface area of the back side of the memory chip 101. During production, underfill (not shown) may be added to the chip package 100 to provide mechanical support to the various components, but during production (before the underfill is added) pressure around the periphery of the memory chip may cause torque that affects the mutual contact and alignment of the ball grid arrays 103, 106. The problem of torque increases as the amount of surface area of the back side of the memory chip 101, not covered by the ball grid array 103, increases.

### BRIEF SUMMARY

In one embodiment, a semiconductor chip comprises an array of electrical contacts and a plurality of vias coupling at least one circuit in the semiconductor chip to the array of electrical contacts. The first one of the electrical contacts of the array of electrical contacts is coupled to N vias of the plurality of vias and a second one of the electrical contacts of the array of electrical contacts is coupled to M vias of the plurality of vias, where M and N are positive integers of different values.

In another embodiment, a semiconductor chip comprises a first and second means for providing electrical contact external to the semiconductor chip. The chip also comprises a first means for coupling to a first circuit in the semiconductor chip, the first circuit coupling means in communication with the first electrical contact means, and a second means for coupling to a second circuit in the semiconductor chip. The second circuit coupling means is in communication with the second electrical contact means. The number of first circuit coupling means is different than a number of second circuit coupling means.

In yet another embodiment, a semiconductor chip manufacturing method comprises fabricating a plurality of vias coupled to least one circuit in the semiconductor chip and fabricating an array of electrical contacts in communication with the plurality of vias. A first one of the electrical contacts of the array of electrical contacts is coupled to N vias of the plurality of vias, and a second one of the electrical contacts of the array of electrical contacts is coupled to M vias of the plurality of vias, where M and M are positive integers of different values.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is an illustration of an exemplary, conventional chip package.

FIG. 2 is an illustration of a conventional, exemplary layout for the memory chip of FIG. 1.

FIG. 3 is an illustration of an exemplary, conventional ball grid array for use with either the memory chip or the logic chip of FIG. 1.

FIG. 4 is an illustration of an exemplary system, adapted according to one embodiment.

FIG. 5 is an illustration of an exemplary process, adapted according to one embodiment.

FIG. 6 is an illustration of an exemplary array, adapted according to one embodiment.

FIG. 7 is an illustration of exemplary arrangements of TSVs relative to input/output contacts for use in some embodiments.

FIG. 8 is an illustration of an exemplary process, adapted according to one embodiment.

FIG. 9 shows an exemplary wireless communication system in which an embodiment of the disclosure may be advantageously employed.

### DETAILED DESCRIPTION

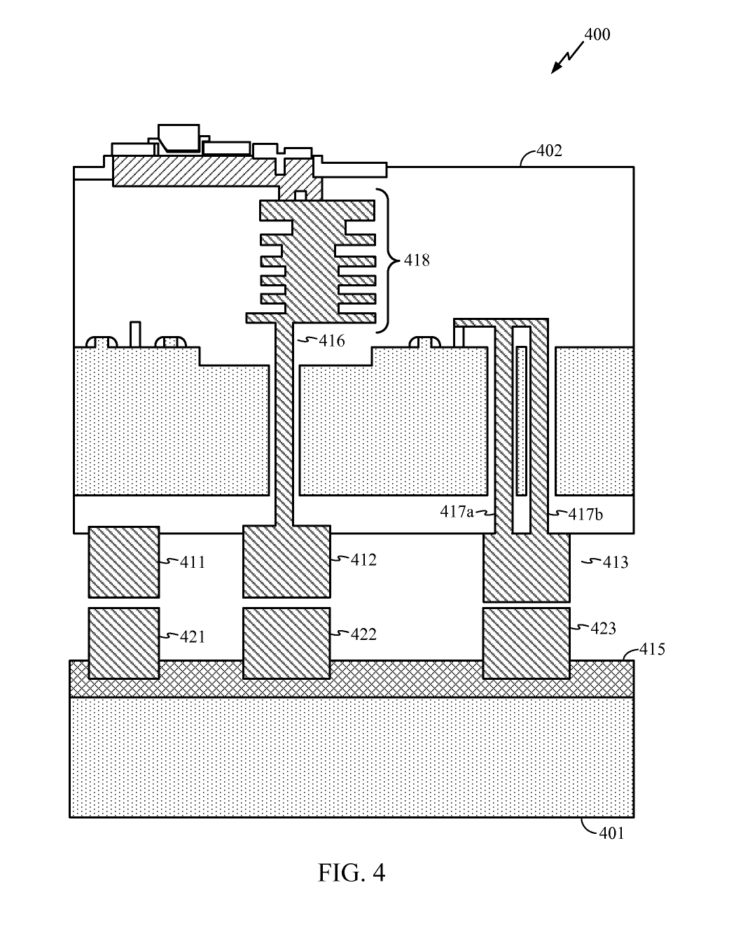

FIG. 4 is an illustration of the exemplary system 400, adapted according to one embodiment. The system 400 includes a logic chip 402 and a memory chip 401. The memory chip 401 includes contacts 422, 423, and the logic chip 402 includes the contacts 412, 413. FIG. 4 shows only four contacts 412, 413, 422, 423 for convenience, but it is understood that various embodiments may include many more contacts arranged in arrays. In FIG. 4, the contacts are arranged in arrays that are aligned to provide electrical contact between the logic chip 402 and the memory chip 401. Specifically, the contacts 422 and 423 are in communication with a redistribution layer 415 to access the various memory units (not shown) in the memory chip 401. Likewise, the contacts 412 and 413 are in communication with logic circuits (not shown) and metal layers 418 by virtue of the Through Silicon Vias (TSVs) 416, 417. Although an RDL is not shown on the logic chip 402 in the embodiment of FIG. 4, an RDL could be provided in alternative embodiments. Furthermore, the use of silicon as a semiconductor material is exemplary, and other embodiments may employ other semiconductor materials.

Turning attention to the TSVs 416, 417, it is noted that the contact 412 is in communication with a single TSV, whereas the contact 413 is in communication with two TSVs. Various embodiments employ different numbers of TSVs for some contacts to improve performance. For instance, in this example, the contact 412 is a signal contact, and the TSV 416 conveys data signals from circuits in the metal layers 418 to the contact 412. Additionally, in this example, the contact 413 is a power contact that receives power through the TSVs 417a and 417b. Generally, as the number of TSVs at a single contact is increased, the resistance decreases while the capacitance increases. On the other hand, generally, as the number of TSVs at a single contact decreases, the resistance increases while the capacitance decreases. The contact 412 is in communication with a single TSV in order to reduce the amount of capacitance between the contact 412 and the circuits in the metal layers 418. On the other hand, the contact 413 is in communication with two TSVs in order to reduce the amount of resistance between the power source (not shown) and the contact 413, and some amount of capacitance can be tolerated, especially in light of the benefit of decreased resistance.

While FIG. 4 shows one exemplary embodiment, the scope of embodiments is not limited to any particular number of TSVs per contact. In some applications, the number of TSVs for a signal contact exceed one, whereas some power contacts may utilize only a single TSV. The number of TSVs serving a given contact may be configured to benefit a design with respect to cost, performance, or other relevant factors. Additionally, various embodiments may employ vias for purposes other than conveying power or signals. For instance, some embodiments may use vias to provide thermal support by moving heat toward the outside of a chip, and such thermal vias may be configured according to the principles described above.

Mechanical support bumps 411, 421 are not in contact with logic circuits or memory units. Instead, mechanical support bumps 411, 421 are placed outside of the areas of the ball grid arrays of each of the chips 401, 402 toward the peripheries of their respective chips to provide mechanical support. In many embodiments, the contacts 412, 413 and 422, 423 are solder balls, and the mechanical support bumps 411 and 421 are balls also manufactured by the same processes that produce the contacts 412, 413 and 422, 423. In other embodiments, mechanical support bumps are fabricated with different processes and/or at different times than the actual electrical contacts. Additionally, the scope of embodiments is not limited to any particular shape of electrical contacts or mechanical support bumps. Furthermore, in some embodiments, it is possible to add mechanical support bumps to one chip but not the other, while providing mechanical support, e.g., by using larger bumps or differently shaped bumps.

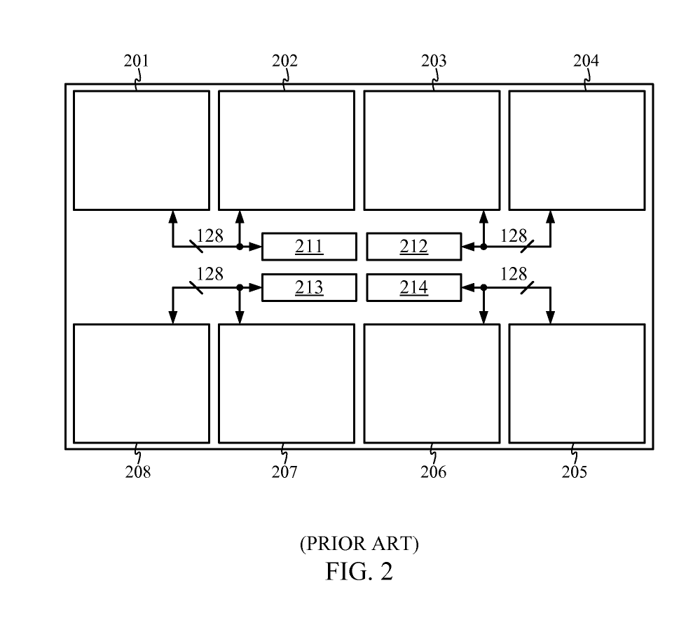

The mechanical support bumps 411, 421 are aligned and placed near the edges of the chips 401 and 402 to ameliorate the effects of mechanical pressure that might otherwise cause torque and disrupt the alignment and/or electrical communication of the contacts 412, 413 and 422, 423. The availability of mechanical support bumps, such as the bumps 411 and 421 can provide flexibility to a designer of chip packages. For instance, the contacts on a memory chip may be placed in arrays near the center of the chip, as shown in FIG. 2. When a memory chip is stacked with a logic chip, there could be good support at the center of the memory chip due to the array connections between the two chips. However, if the surface area of the memory chip is larger than the area of the contact array of the memory chip, there is little mechanical support near the edges of the memory chip, subjecting the stack to mechanical failure when forces are applied near the edges of the memory chip.

A designer of a chip package can add mechanical support bumps to memory chips and/or logic chips to increase mechanical support. The availability of mechanical support bumps may allow a designer to choose from amongst a variety of memory chips, some with large surface areas compared to the areas of their respective contact arrays. The designer may add mechanical support bumps during fabrication of the chips or later when the chips are stacked.

While the embodiments above include one memory chip and one logic chip, the scope of embodiments is not so limited. For instance, various embodiments may apply mechanical support bumps to any kind of stacked-chip arrangement, regardless of the type of chips or number of chips used.

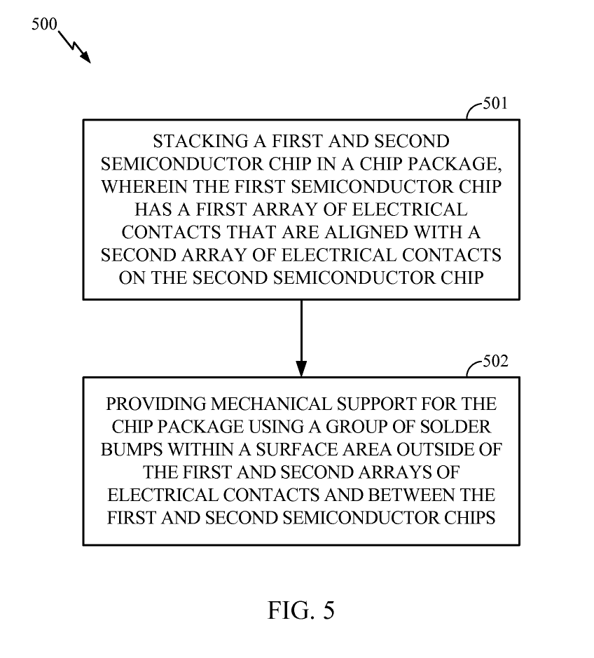

FIG. 5 is an illustration of an exemplary process 500, adapted according to one embodiment. The process 500 may be performed, e.g., by a person and/or machine fabricating a semiconductor chip package.

In block 501, a first and a second semiconductor chip are stacked in a chip package. The first semiconductor chip has a first array of electrical contacts that are aligned with a second array of electrical contacts on the second semiconductor chip. Either or both of the semiconductor chips may include vias arranged therein to optimize one or more factors (e.g., performance), as discussed above with respect to FIG. 4. In block 502, mechanical support for the chip package is provided using bumps within a surface area outside of the first and second arrays of electrical contacts and between the first and second semiconductor chips. The bumps can be placed, e.g., based on where mechanical support is most effective. For instance, the bumps can be placed at or near corners of the smaller of the chips, in the vicinity of one or more edges of the smaller of the chips, and/or anywhere else that might be helpful. The bumps can be fabricated according to any of a variety of techniques now known or later developed. In one example, an under bump metal layer (UBM) is deposited on a wafer, providing an electrode for electrical plating. A lithography process is performed to pattern a resist on the wafer, where the areas to form bumps will have no resist. The wafer is submerged into a plating solution with the wafer biased as the cathode. Metal (e.g., Cu, Sn and/or the like) is deposited on the target area. After completing plating, the resist is stripped. The UBM on open field is removed by wet chemistry.

While process 500 is shown as a series of discrete processes, the scope of embodiments is not so limited. Various embodiments may add, omit, rearrange, or modify the actions of the process 500. For instance, in some embodiments, the bumps are added before the semiconductor chips are stacked, such as during the fabrication of the individual semiconductor chips. In other embodiments the bumps may even be added after the semiconductor chips are fabricated. In various embodiments, the process 500 may include further actions, such as adding underfill and/or incorporating the chip package into a device, e.g., a cell phone, a computer, a navigation device, or the like.

The example embodiments above show techniques for providing mechanical support, including the use of mechanical support bumps. The examples below illustrate techniques for providing electrical communication between two or more stacked chips as well as between electrical contacts and circuits within a chip.

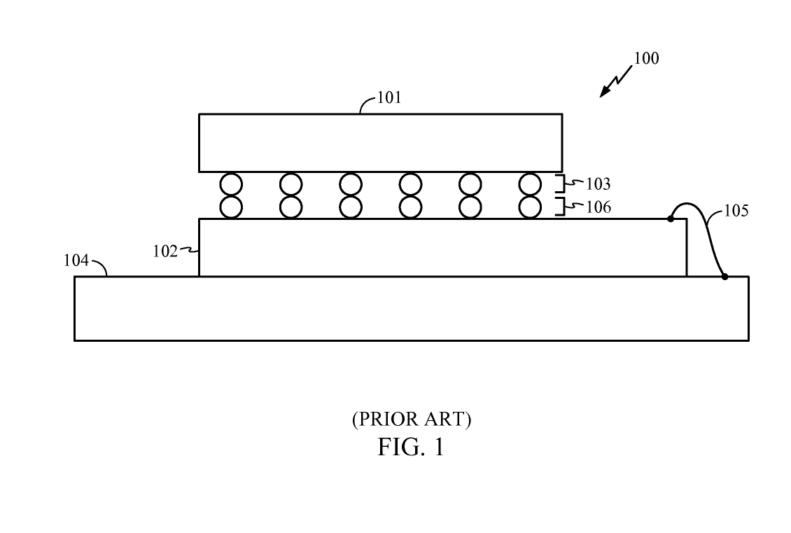

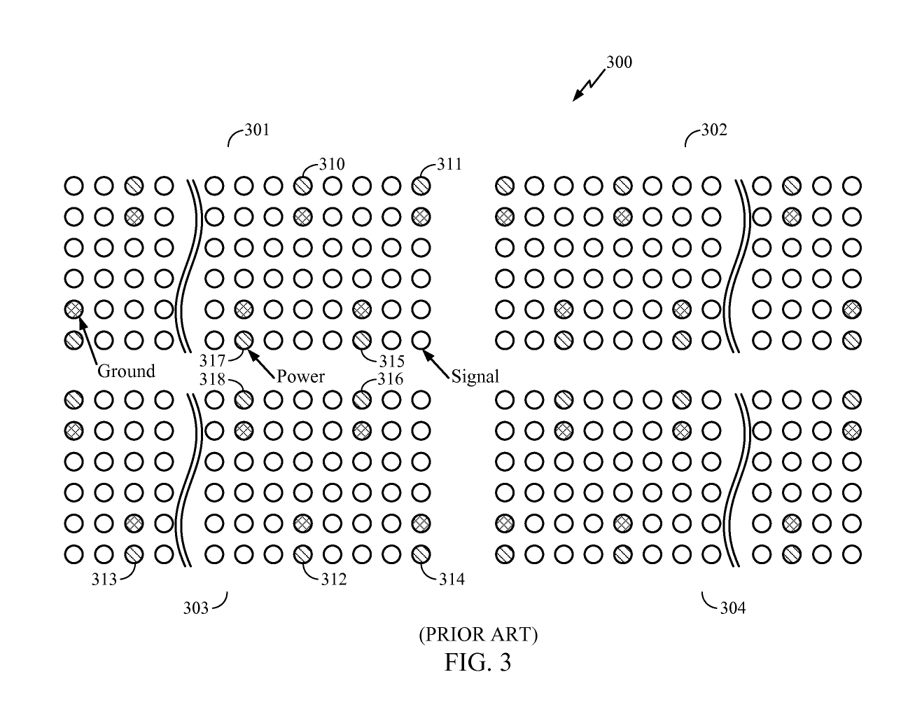

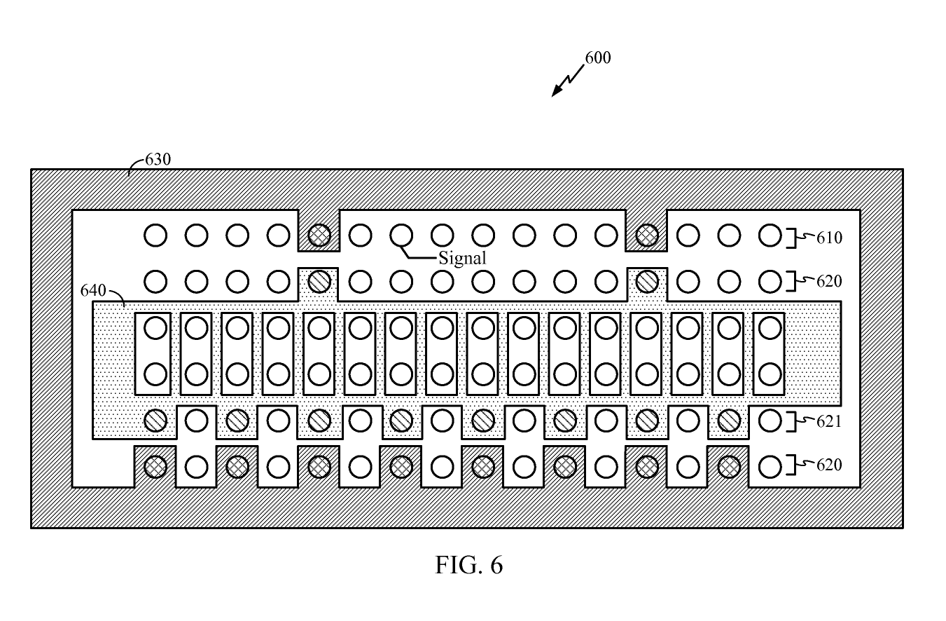

FIG. 6 is an illustration of an exemplary array 600, adapted according to one embodiment. The array 600 of contacts can be used in memory and logic chips, such as the chips of FIGS. 1 and 4. In contrast to the layout of FIG. 3, the power and ground contacts are clustered near the periphery of the array and away from the center of the array. For instance, the power contacts are arranged in rows 610 and 611, and the ground contacts are arranged in rows 620 and 621. The power contacts are in communication with the power metal layer 630. Similarly, the ground contacts are in communication with the ground metal layer 640, which, in this example, includes a single BGA Semiauto Mounter (BSM) shape.

The result of the arrangement shown in FIG. 6 is to keep the power contacts near other power contacts, the ground contacts near other ground contacts, and both the power and ground contacts are placed proximate power and ground metal layers. Furthermore, even though the ground metal layer 640 is proximate the center of the array 600, the ground contacts (and power contacts) and excluded from the center of the array. In contrast to the conventional array shown in FIG. 3, the array of FIG. 6 aligns the contacts in a manner that allows more of the contacts to be shorted by a flood-type area rather than as separate BSM islands. In other words, the example layout of FIG. 6 arranges the contacts so that one V_{DD} (power) node shorts the power contacts, and one V_{SS} (ground) node shorts the ground contacts, which is a more efficient arrangement, at least in terms of routing resources, than is the array of FIG. 3.

FIG. 6 shows an array that is not divided into multiple channels, but the scope of embodiments is not so limited. In another example, an array is divided into four channels. Many embodiments include an N by M arrangement of channels, where N and M can be any integer greater than zero. Any array of contacts can be adapted according to a variety of embodiments.

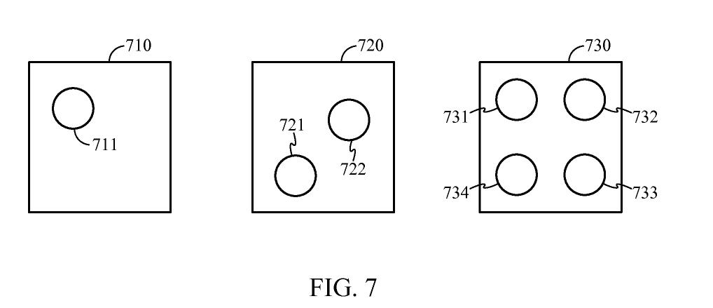

FIG. 7 is an illustration of exemplary arrangements of TSVs relative to input/output contacts (e.g., solder balls) for use in some embodiments. FIG. 7 provides a top-down view of contacts (e.g., solder bumps) 710, 720, and 730 with dots shown therein to illustrate possible placement of TSVs with respect to each of the contacts 710, 720, and 730. Each of the TSVs may provide electrical or thermal communication between a given contact and one or more logic circuits or memory units (not shown) inside a semiconductor chip.

As shown, the contact 710 is in communication with one TSV 711, whereas the contact 720 is in communication with two TSVs 721, 722. The contact 730 is in communication with four TSVs 731-734. The shapes of the contacts 710, 720, and 730, as well as the relative placements and numbers of the TSVs are exemplary and may differ in other embodiments. Arrangements of TSVs according to the principles of FIG. 7 can be adapted for use with the arrays of contacts in FIGS. 1 and 4.

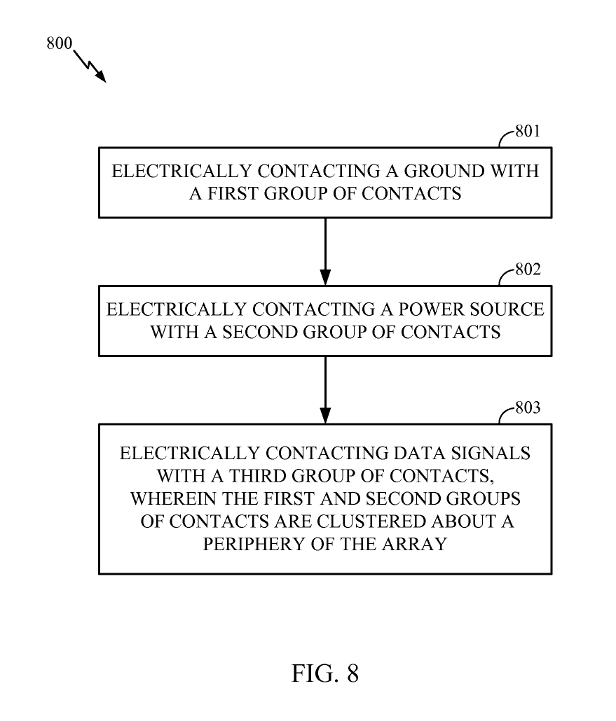

FIG. 8 is an illustration of an exemplary process 800, adapted according to one embodiment. The process 800 may be performed, e.g., by a person and/or machine fabricating a semiconductor chip package.

In block 801, a ground is electrically contacted with a first group of contacts. In block 802, a power source is electrically contacted with a second group of contacts. In some embodiments the contacts include solder bumps in a ball grid array, and the power source and ground include metal layers. Electrical communication between the ground/power source and the contacts can be made in any of a variety of ways, including through the use of TSVs and/or an RDL. TSVs can be arranged to affect one or more relevant factors (e.g., resistance and/or capacitance), as discussed above with respect to FIG. 4.

In block 803, data lines electrically contact a third group of contacts. Data signals on the data lines can be received from a memory unit or a logic circuit and can be conveyed through use of TSVs and/or RDLs. The first and second groups of contacts are clustered about a periphery of the array. The arrangement of the power and ground contacts is such that the power and ground contacts are not near the center of the array of contacts, but rather, are arranged around the periphery of the array, as shown in FIG. 6.

While process 800 is shown as a series of discrete processes, the scope of embodiments is not so limited. Various embodiments may add, omit, rearrange, or modify the actions of the process 800. For instance, in some embodiments, the contacts and their electrical connections are fabricated at the same time using the same processes. Furthermore, the process 800 may include further processing, such as aligning the array with an array on another chip and stacking the chips so that the chips communicate with each other. Semiconductor chips manufactured according to the process 800 can be incorporated into any of a variety of processor-based devices.

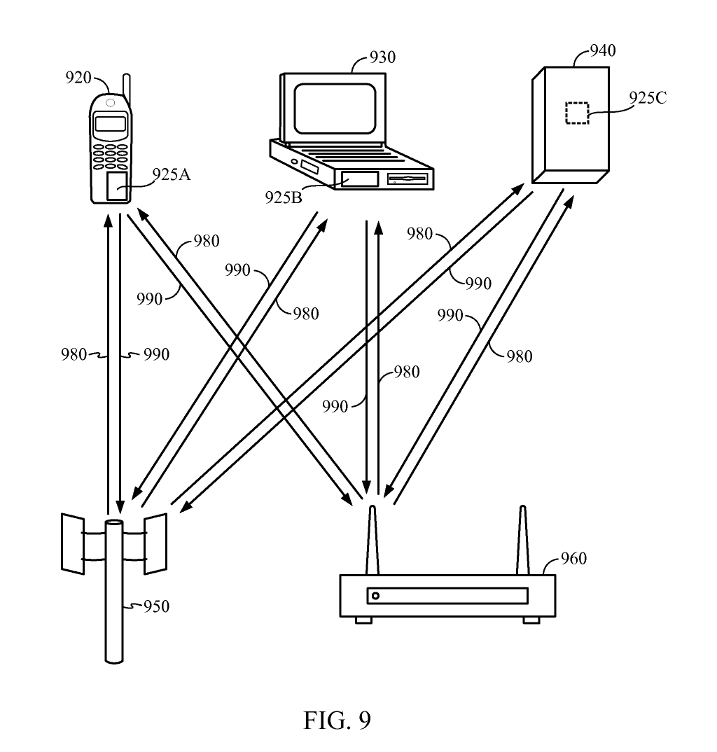

FIG. 9 shows an exemplary wireless communication system 900 in which an embodiment of the disclosure may be advantageously employed. For purposes of illustration, FIG. 9 shows three remote units 920, 930, and 940 and two base stations 950, 960. It will be recognized that wireless communication systems may have many more remote units and base stations. The remote units 920, 930, and 940 include improved semiconductor devices 925A, 925B, and 925C, respectively, which in various embodiments include improved electrical contact arrangements and/or internal mechanical support structures, as discussed above. FIG. 9 shows the forward link signals 980 from the base stations 950, 960 and the remote units 920, 930, and 940 and the reverse link signals 990 from the remote units 920, 930, and 940 to base stations 950, 960.

In FIG. 9, the remote unit 920 is shown as a mobile telephone, the remote unit 930 is shown as a portable computer, and the remote unit 940 is shown as a computer in a wireless local loop system. For example, the remote unit 920 may include mobile devices, such as cell phones, hand-held personal communication systems (PCS) units, portable data units such as personal data assistants. The remote unit 920 may also include fixed location data units such as meter reading equipment. Although FIG. 9 illustrates remote units according to the teachings of the disclosure, the disclosure is not limited to these exemplary illustrated units. The disclosure may be suitably employed in any device which includes a semiconductor chip. Although specific circuitry has been set forth, it will be appreciated by those skilled in the art that not all of the disclosed circuitry is required to practice the disclosure. Moreover, certain well known circuits have not been described in order to maintain focus on the disclosure.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor chip comprising:
an array of electrical contacts; and
a plurality of vias coupling at least one circuit in the semiconductor chip to the array of electrical contacts, in which a first one of the electrical contacts of the array of electrical contacts is coupled to N vias of the plurality of vias, and in which a second one of the electrical contacts of the array of electrical contacts is coupled to M vias of the plurality of vias, where M and N are positive integers of different values.

2. The semiconductor chip of claim 1 in which the first electrical contact comprises a power contact, and in which the second electrical contact comprises a signal contact, and further in which M is larger than N.

3. The semiconductor chip of claim 1 in which the plurality of vias comprises at least one thermal via.

4. The semiconductor chip of claim 1 in which the plurality of vias comprises Through Silicon Vias (TSVs).

5. The semiconductor chip of claim 1 in which the N vias couple directly to the first electrical contact.

6. The semiconductor chip of claim 1 in which the N vias couple to the first electrical contact through a redistribution layer.

7. The semiconductor chip of claim 1 further comprising:
a plurality of support bumps outside of the array of electrical contacts, the support bumps providing mechanical support for a chip package that includes the semiconductor chip.

8. The semiconductor chip of claim 7 in which the first semiconductor chip comprises a logic chip that is coupled to a memory chip in the chip package.

9. The semiconductor chip of claim 1 in which the array of electrical contacts comprises:
a plurality of ground contacts;
a plurality of power contacts; and
a plurality of signal contacts, the plurality of power contacts and the plurality of ground contacts being clustered about a periphery of the array of electrical contacts.

10. The semiconductor chip of claim 1 incorporated into a device selected from a group consisting of a music player, a video player, an entertainment unit, a navigation device, a communications device, a personal digital assistant (PDA), a fixed location data unit, and a computer.

11. A semiconductor chip comprising:
first means for providing electrical contact external to the semiconductor chip
second means for providing electrical contact external to the semiconductor chip;
first means for coupling to a first circuit in the semiconductor chip, the first circuit coupling means in communication with the first electrical contact means; and
second means for coupling to a second circuit in the semiconductor chip, the second circuit coupling means in communication with the second electrical contact means;
in which a number of first circuit coupling means is different than a number of second circuit coupling means.

12. The semiconductor chip of claim 11 in which the first and second electrical contact means comprise solder balls in a ball grid array.

13. The semiconductor chip of claim 11 in which the first and second circuit coupling means comprise Through Silicon Vias (TSVs).

14. The semiconductor chip of claim 11 in which the first electrical contact means comprise a power contact, and in which the second electrical contact means comprise a signal contact.

15. The semiconductor chip of claim 14 in which in which the number of first circuit coupling means is larger than the number of second circuit coupling means.

16. The semiconductor chip of claim 11 in which the semiconductor chip is included in a chip package with a memory chip, in which the first and second electrical contact means provide electrical communication with a plurality of contacts on the memory chip.

17. The semiconductor chip of claim 11 incorporated into a device selected from a group consisting of a music player, a video player, an entertainment unit, a navigation device, a communications device, a personal digital assistant (PDA), a fixed location data unit, and a computer.

18. A method of manufacturing a semiconductor chip, the manufacturing method comprising:
fabricating a plurality of vias coupled to least one circuit in the semiconductor chip; and
fabricating an array of electrical contacts in communication with the plurality of vias, in which a first one of the electrical contacts of the array of electrical contacts is coupled to N vias of the plurality of vias, and in which a second one of the electrical contacts of the array of electrical contacts is coupled to M vias of the plurality of vias, where M and M are positive integers of different values.

19. The method of claim 18 further comprising:
stacking the semiconductor chip with another semiconductor chip in a chip package.

20. The method of claim 18 further comprising:
incorporating the semiconductor chip into a device selected from a group consisting of a music player, a video player, an entertainment unit, a navigation device, a communications device, a personal digital assistant (PDA), a fixed location data unit, and a computer.

21. A method of manufacturing a semiconductor chip, the manufacturing method comprising the steps of:
fabricating a plurality of vias coupled to least one circuit in the semiconductor chip; and
fabricating an array of electrical contacts in communication with the plurality of vias, in which a first one of the electrical contacts of the array of electrical contacts is coupled to N vias of the plurality of vias, and in which a second one of the electrical contacts of the array of electrical contacts is coupled to M vias of the plurality of vias, where M and M are positive integers of different values.

22. The method of claim 21 in which the array of electrical contacts comprises solder bumps.

23. The method of claim 21 further comprising:
stacking the semiconductor chip with another semiconductor chip in a chip package.

24. The method of claim 21 further comprising:
incorporating the semiconductor chip into a device selected from a group consisting of a music player, a video player, an entertainment unit, a navigation device, a communications device, a personal digital assistant (PDA), a fixed location data unit, and a computer.
